(19) United States
(12) Patent Application Publication
(10) Pub. No.: US 2026/0159936 A1
(43) Pub. Date: Jun. 11, 2026

(54) DEPOSITION MASK, METHOD OF MANUFACTURING THE SAME, AND ELECTRONIC DEVICE MANUFACTURED BY USING THE SAME

(71) Applicant: Samsung Display Co., LTD., Yongin-si (KR)

(72) Inventors: Jeong Kuk KIM, Yongin-si (KR); Sung Woon KIM, Yongin-si (KR); Na Rae PARK, Yongin-si (KR); Deok Chan YOON, Yongin-si (KR); Duck Jung LEE, Yongin-si (KR); Ji Hyun JUNG, Yongin-si (KR)

(21) Appl. No.: 19/179,568

(22) Filed: Apr. 15, 2025

(30) Foreign Application Priority Data
Aug. 14, 2024 (KR) 10-2024-0109088

(51) Int. Cl. C23C 14/04; H10K 71/16

(52) U.S. Cl. CPC C23C 14/042; H10K 71/166

(57) ABSTRACT

A deposition mask includes a mask frame defining a cell opening, an intermediate inorganic film disposed on the mask frame and defining an intermediate opening defined on the cell opening, and a membrane disposed on the intermediate inorganic film and defining a plurality of pixel openings defined on the intermediate opening. The intermediate opening has a width greater than a width of the cell opening such that a groove having a band shape is defined between the mask frame and the membrane.

This application claims priority to Korean Patent Application No. 10-2024-0109088, filed on Aug. 14, 2024, and all the benefits accruing therefrom under 35 U.S.C. § 119, the content of which in its entirety is herein incorporated by reference.

### BACKGROUND

### 1. Field

The disclosure relates to a deposition mask, a method of manufacturing the same, and an electronic device manufactured by the same.

### 2. Description of the Related Art

Wearable devices in which a focus is formed at a distance close to user's eyes have been developed in the form of glasses or a helmet. For example, the wearable device may be a head mounted display (“HMD”) device or augmented reality (“AR”) glasses. The wearable device may provide an AR screen or a virtual reality (“VR”) screen to a user.

In the case of wearable devices such as the HMD device or the AR glasses, a display specification of approximately 3000 pixels per inch (PPI) or higher is desired to allow users to use them for a long time without symptoms of dizziness. To this end, organic light emitting diode on silicon (“OLEDoS”) technology used in high-resolution small-sized organic light emitting display devices is emerging. The OLEDoS is a technology in which organic light emitting diodes (“OLEDs”) are disposed on a semiconductor substrate on which complementary metal oxide semiconductor (“CMOS”) elements are disposed.

In order to manufacture a display panel with a relatively high resolution of about 3000 PPI or higher, a high-resolution deposition mask is desired. In an embodiment, the deposition mask may be manufactured by forming a membrane defining a plurality of pixel openings on a substrate such as a silicon wafer, and partially etching the substrate to define cell openings that expose the pixel openings.

### SUMMARY

A deposition mask may be used in a deposition process for forming organic light emitting layers on a backplane substrate. While the deposition process is being performed, the backplane substrate may be disposed on the deposition mask, and a deposition source for providing a vapor deposition material may be disposed under the deposition mask. The vapor deposition material may be deposited on the backplane substrate through pixel openings of the deposition mask. In this case, the vapor deposition material may also be deposited on the deposition mask, and a deposition material layer formed on the deposition mask may be removed through a cleaning process. For example, the deposition material layer on the deposition mask may be removed through an ultrasonic cleaning process using an N-methyl-2-pyrrolidone (“NMP”) cleaning solution. However, there may arise a problem that a membrane may be damaged by ultrasonic vibration during the ultrasonic cleaning process.

Advantages and features of embodiments of the disclosure provide an improved deposition mask capable of solving the problem of a membrane being damaged in an ultrasonic cleaning process, a method of manufacturing the same, and an electronic device manufactured by the same.

However, embodiments of the disclosure are not limited to those set forth herein. The above and other embodiments of the disclosure will become more apparent to one of ordinary skill in the art to which the disclosure pertains by referencing the detailed description of the disclosure given below.

In an embodiment of the disclosure, a deposition mask may include a mask frame defining a cell opening, an intermediate inorganic film disposed on the mask frame and defining an intermediate opening defined on the cell opening, and a membrane disposed on the intermediate inorganic film and defining a plurality of pixel openings defined on the intermediate opening. The intermediate opening may have a width greater than a width of the cell opening such that a groove having a band shape is defined between the mask frame and the membrane.

In an embodiment, a lower width of the intermediate opening may be greater than an upper width of the cell opening, and an upper width of the intermediate opening may be smaller than the lower width of the intermediate opening.

In an embodiment, a lower width of the cell opening may be greater than the upper width of the cell opening.

In an embodiment, the intermediate inorganic film may define a plurality of recesses arranged along a circumference of the intermediate opening and extended to the intermediate opening. In such case, the membrane may define a plurality of through holes defined on the recesses, and an upper width of the recesses may be greater than a lower width of the recesses.

In an embodiment, the intermediate inorganic film may define a plurality of recesses arranged along a circumference of the intermediate opening, extending along the circumference of the intermediate opening, and extended to the intermediate opening. In such case, the membrane may define a plurality of through slots defined on the recesses and extending in a same direction as an extension direction of the recesses, and an upper width of the recesses may be greater than a lower width of the recesses.

In an embodiment, the mask frame may include silicon, the membrane may include silicon nitride, and the intermediate inorganic film may include silicon oxide.

In an embodiment of the disclosure, a method of manufacturing a deposition mask may include forming an intermediate inorganic film on a substrate, forming a membrane on the intermediate inorganic film, patterning the membrane to define a plurality of pixel openings exposing the intermediate inorganic film, patterning the substrate to define a cell opening exposing the intermediate inorganic film, and patterning the intermediate inorganic film to define an intermediate opening extending to the plurality of pixel openings and the cell opening. The intermediate opening may have a width greater than a width of the cell opening such that a groove having a band shape is defined between the substrate and the membrane.

In an embodiment, the intermediate opening may be defined by a wet etching process, a lower width of the intermediate opening may be greater than an upper width of the cell opening, and an upper width of the intermediate opening may be smaller than the lower width of the intermediate opening.

In an embodiment, the cell opening may be defined by a wet etching process, and a lower width of the cell opening may be greater than the upper width of the cell opening.

In an embodiment, the method may further include patterning the intermediate inorganic film to define a plurality of recesses arranged along a circumference of the intermediate opening and extended to the intermediate opening. Further, the method may include patterning the membrane to define a plurality of through holes exposing the intermediate inorganic film. In such case, the through holes may be arranged in a band shape surrounding the plurality of pixel openings and are defined simultaneously with the plurality of pixel openings. Further, the recesses may be extended to the through holes and may be defined simultaneously with the intermediate opening by a wet etching process, and an upper width of the recesses may be greater than a lower width of the recesses.

In an embodiment, the method may further include patterning the intermediate inorganic film to define a plurality of recesses arranged along a circumference of the intermediate opening, extending along the circumference of the intermediate opening, and extended to the intermediate opening. Further, the method may include patterning the membrane to define a plurality of through slots exposing the intermediate inorganic film. In such case, the through slots may be arranged in a band shape surrounding the plurality of pixel openings, may extend in a same direction as an extension direction of the recesses, and may be defined simultaneously with the plurality of pixel openings. Further, the recesses may be extended to the through slots and may be defined simultaneously with the intermediate opening by a wet etching process, and an upper width of the recesses may be greater than a lower width of the recesses.

In an embodiment, the substrate may include silicon, the membrane may include silicon nitride, and the intermediate inorganic film may include silicon oxide.

In an embodiment of the disclosure, an electronic device may include a display panel. The display panel may include a backplane substrate and light-emitting layers formed on the backplane substrate by a deposition mask. The deposition mask may include a mask frame defining a cell opening, an intermediate inorganic film disposed on the mask frame and defining an intermediate opening defined on the cell opening, and a membrane disposed on the intermediate inorganic film and defining a plurality of pixel openings defined on the intermediate opening. The intermediate opening may have a width greater than a width of the cell opening such that a groove having a band shape is defined between the mask frame and the membrane.

By embodiments of the disclosure, an upper edge of a cell opening may be spaced apart from a membrane by an intermediate opening, so that damage to the upper edge of the cell opening and the membrane may be prevented during an ultrasonic cleaning process for a deposition mask.

Other features and embodiments may be apparent from the following detailed description and the drawings.

### BRIEF DESCRIPTION OF THE DRAWINGS

The above and other advantages and features of the disclosure will become more apparent by describing in detail embodiments thereof with reference to the attached drawings, in which:

FIG. 1 is an exploded perspective view illustrating a display device;

FIG. 2 is a block diagram for explaining the display device shown in FIG. 1;

FIG. 3 is an equivalent circuit diagram for explaining an embodiment of a first sub-pixel shown in FIG. 2;

FIG. 4 is a schematic plan view illustrating an embodiment of the display panel shown in FIG. 1;

FIG. 5 is a schematic plan view illustrating an embodiment of the display area shown in FIG. 4;

FIG. 6 is a schematic plan view illustrating another embodiment of the display area shown in FIG. 4;

FIG. 7 is a cross-sectional view illustrating an embodiment of the display panel taken along line I-I′ of FIG. 5;

FIG. 8 is a schematic perspective view illustrating an embodiment of a head mounted display;

FIG. 9 is a schematic exploded perspective view illustrating the head mounted display shown in FIG. 8;

FIG. 10 is a schematic perspective view illustrating another embodiment of a head mounted display;

FIG. 11 is a schematic view illustrating an embodiment of a deposition mask and a deposition apparatus including the same according to the disclosure;

FIG. 12 is a schematic bottom view illustrating a backplane substrate as shown in FIG. 11;

FIG. 13 is a schematic plan view illustrating a deposition mask as shown in FIG. 11;

FIG. 14 is a schematic enlarged plan view illustrating mask cell regions as shown in FIG. 13;

FIG. 15 is a schematic cross-sectional view taken along line II-II′ as shown in FIG. 14;

FIG. 16 is a schematic enlarged cross-sectional view illustrating an intermediate inorganic film as shown in FIG. 15;

FIG. 17 is a schematic cross-sectional view illustrating a conventional deposition mask;

FIG. 18 is a schematic plan view illustrating another embodiment of a deposition mask according to the disclosure;

FIG. 19 is a schematic enlarged cross-sectional view illustrating recesses as shown in FIG. 18;

FIG. 20 is a schematic plan view illustrating another embodiment of a deposition mask according to the disclosure;

FIG. 21 is a schematic enlarged cross-sectional view illustrating recesses as shown in FIG. 20;

FIGS. 22 to 26 are schematic cross-sectional views illustrating another embodiment of a method of manufacturing a deposition mask according to the disclosure;

FIGS. 27 and 28 are schematic cross-sectional views illustrating another embodiment of a method of manufacturing a deposition mask according to the disclosure; and

FIGS. 29 and 30 are schematic cross-sectional views illustrating another embodiment of a method of manufacturing a deposition mask according to the disclosure.

### DETAILED DESCRIPTION

Embodiments of the disclosure will now be described more fully hereinafter with reference to the accompanying drawings, in which various embodiments of the disclosure are shown. This invention may, however, be embodied in different forms and should not be construed as limited to the embodiments set forth herein. Rather, these embodiments are provided so that this disclosure will be thorough and complete, and will filly convey the scope of the disclosure to those skilled in the art.

It will also be understood that when an element or a layer is referred to as being “on” another element or layer, it may be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Drawing figures. It will be understood that relative terms are intended to encompass different orientations of the device in addition to the orientation depicted in the Drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

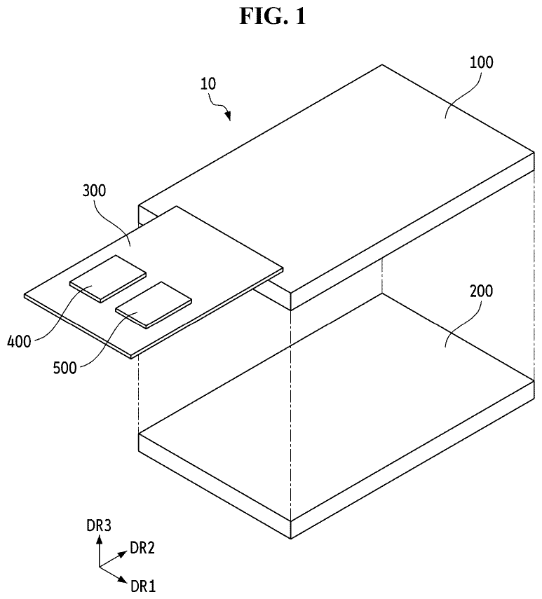

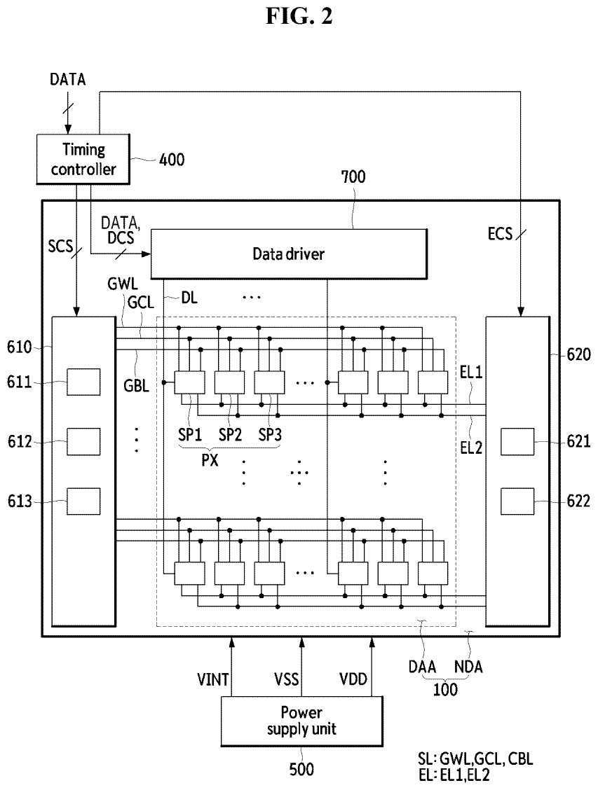

FIG. 1 is an exploded perspective view illustrating a display device. FIG. 2 is a block diagram for explaining the display device shown in FIG. 1.

Referring to FIGS. 1 and 2, a display device 10 may be a device displaying a moving image or a still image. The display device 10 may be applied to portable electronic devices such as, e.g., a mobile phone, a smartphone, a tablet personal computer (“PC”), a mobile communication terminal, an electronic organizer, an electronic book, a portable multimedia player (“PMP”), a navigation system, an ultra mobile PC (“UMPC”) or the like. In an embodiment, the display device 10 may be applied as a display unit of electronic devices such as, e.g., a television, a laptop, a monitor, a billboard, an Internet-of-Things (“IoT”) device, or the like, for example. In an alternative embodiment, the display device 10 may be applied to electronic devices such as, e.g., a smart watch, a watch phone, a head mounted display (“HMD”) for implementing virtual reality and augmented reality, or the like.

The display device 10 may include a display panel 100, a heat dissipation layer 200, a circuit board 300, a timing control circuit 400, and a power supply circuit 500.

The display panel 100 may have a planar shape similar to a quadrilateral shape. In an embodiment, the display panel 100 may have a planar shape similar to a quadrilateral shape, including a short side of a first direction DR1 and a long side of a second direction DR2 intersecting the first direction DR1, for example. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the disclosure is not limited thereto.

The display panel 100 may include a plurality of pixels PX, a plurality of scan lines SL, a plurality of emission control lines EL, a plurality of data lines DL, a scan driver 610, an emission driver 620, and a data driver 700. As shown in FIG. 2, the display panel 100 may be divided into a display area DAA displaying an image and a non-display area NDA not displaying an image.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

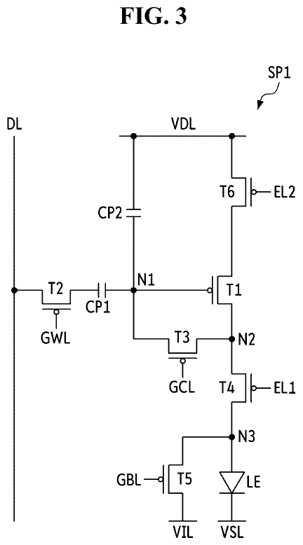

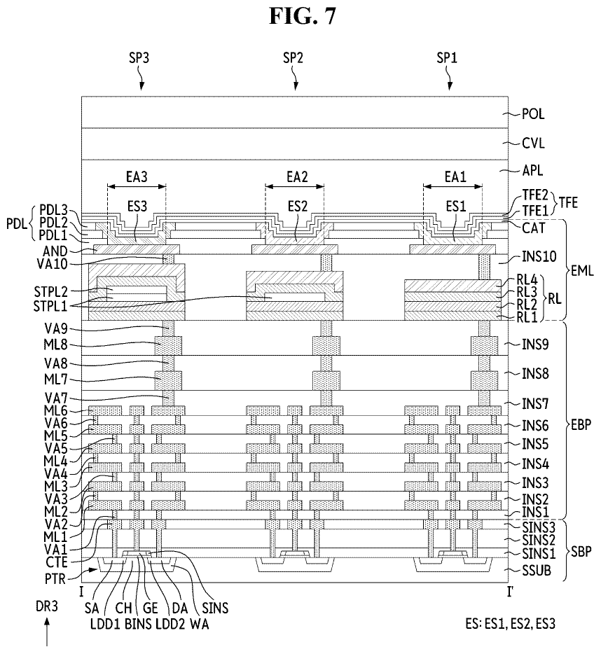

The plurality of pixels PX may include a plurality of sub-pixels SP1, SP2, and SP3. The plurality of sub-pixels SP1, SP2, and SP3 may include a plurality of pixel transistors (refer to FIG. 3). The plurality of pixel transistors may be formed by a semiconductor process, and may be disposed on a semiconductor substrate SSUB (refer to FIG. 7). In an embodiment, the plurality of pixel transistors of the data driver 700 may be formed through a complementary metal oxide semiconductor (“CMOS”) process, for example, but the disclosure is not limited thereto.

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 may include a plurality of scan transistors, and the emission driver 620 may include a plurality of light-emitting transistors. The plurality of scan transistors and the plurality of light-emitting transistors may be formed on the semiconductor substrate SSUB (refer to FIG. 7) through a semiconductor process. In an embodiment, the plurality of scan transistors and the plurality of light-emitting transistors may be formed through a CMOS process, for example, but the embodiment of the specification is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed through a semiconductor process, and formed on the semiconductor substrate SSUB (refer to FIG. 7). In an embodiment, the plurality of data transistors may be formed through a CMOS process, for example, but the disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, e.g., on the rear surface thereof. The heat dissipation layer 200 serves to dissipate heat generated from the display panel 100. The heat dissipation layer 200 may include a metal layer having relatively high thermal conductivity, such as graphite, silver (Ag), copper (Cu), or aluminum (Al).

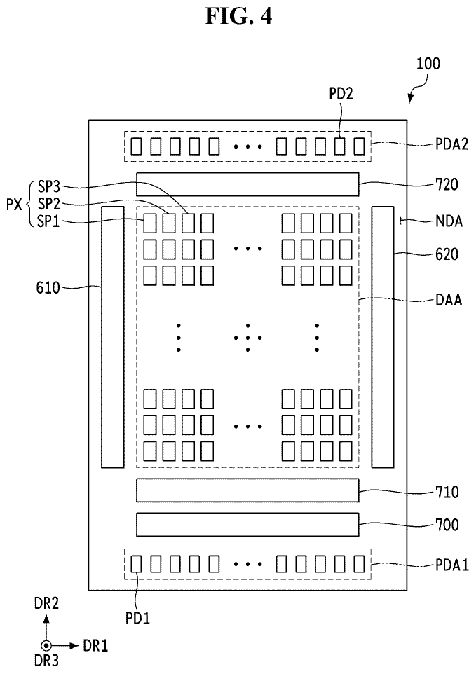

The circuit board 300 may be electrically connected to a plurality of first pads PD1 (refer to FIG. 4) of a first pad portion PDA1 (refer to FIG. 4) of the display panel 100 by a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. An opposite end of the circuit board 300 may be connected to the plurality of first pads PD1 (refer to FIG. 4) of the first pad portion PDA1 (refer to FIG. 4) of the display panel 100 by a conductive adhesive member. One end of the circuit board 300 may be opposite to the opposite end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. In an embodiment, the power supply circuit 500 may generate a first driving voltage VSS, a second driving voltage VDD, and a third driving voltage VINT and supply them to the display panel 100, for example. The first driving voltage VSS, the second driving voltage VDD, and the third driving voltage VINT will be described later in conjunction with FIG. 3.

Each of the timing control circuit 400 and the power supply circuit 500 may be formed as an integrated circuit (“IC”) and attached to one surface of the circuit board 300. In this case, the scan timing control signal SCS, the emission timing control signal ECS, digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In another embodiment, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process, and formed on the semiconductor substrate SSUB (refer to FIG. 7). In an embodiment, the plurality of timing transistors and the plurality of power transistors may be formed through a CMOS process, for example, but the disclosure is not limited thereto. Each of the timing control circuit 400 and the power supply circuit 500 may be disposed between the data driver 700 and the first pad portion PDA1 (refer to FIG. 4).

FIG. 3 is an equivalent circuit diagram for explaining an embodiment of a first sub-pixel shown in FIG. 2.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a relatively low potential voltage is applied, a second driving voltage line VDL to which the second driving voltage VDD corresponding to a relatively high potential voltage is applied, and a third driving voltage line VIL to which the third driving voltage VINT corresponding to an initialization voltage is applied. That is, the first driving voltage line VSL may be a relatively low potential voltage line, the second driving voltage line VDL may be a relatively high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 may include a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the disclosure is not limited thereto. In an embodiment, the light-emitting element LE may be an inorganic light-emitting element including a first electrode, a second electrode, and an inorganic semiconductor disposed between the first electrode and the second electrode, in which case the light-emitting element LE may be a micro light-emitting diode, for example.

The first transistor T1 may be a driving transistor that controls a source-drain current (hereinafter referred to as “driving current”) flowing between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node N1 and the drain electrode of the second transistor T2. The first capacitor CP1 may include one electrode connected to the drain electrode of the second transistor T2 and a remaining (the other) electrode connected to the first node N1.

The second capacitor CP2 is formed between the gate electrode of the first transistor T1 and the second driving voltage line VDL. The second capacitor CP2 may include one electrode connected to the gate electrode of the first transistor T1 and a remaining (the other) electrode connected to the second driving voltage line VDL.

The first node N1 is a junction between the gate electrode of the first transistor T1, the drain electrode of the third transistor T3, a remaining (the other) electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (“MOSFET”). In an embodiment, each of the first to sixth transistors T1 to T6 may be a P-type MOSFET, for example, but the disclosure is not limited thereto. Each of the first to sixth transistors T1 to T6 may be an N-type MOSFET. In an alternative embodiment, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. In an embodiment, the number of transistors and the number of capacitors of the first sub-pixel SP1 are not limited to those shown in FIG. 3, for example.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 will be omitted in the disclosure.

FIG. 4 is a schematic plan view illustrating an embodiment of the display panel shown in FIG. 1.

Referring to FIG. 4, the display area DAA of the display panel 100 may include the plurality of pixels PX arranged in a matrix form. The non-display area NDA of the display panel 100 may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. In an embodiment, the scan driver 610 may be disposed on one side of the display area DAA in the first direction DR1, and the emission driver 620 may be disposed on an opposite side of the display area DAA in the first direction DR1, for example. That is, as shown in FIG. 4, the scan driver 610 may be disposed on the left side of the display area DAA, and the emission driver 620 may be disposed on the right side of the display area DAA. However, the disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. In an embodiment, the first pad portion PDA1 may be disposed on one side of the display area DAA in the second direction DR2, for example. The first pad portion PDA1 may be disposed outside the data driver 700 in the second direction DR2. That is, as shown in FIG. 4, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or probe pins during an inspection process, or may be connected to a circuit board for inspection. The circuit board for inspection may be a printed circuit board including or consisting of a rigid material or a flexible printed circuit board including or consisting of a flexible material.

The second pad portion PDA2 may be disposed on the fourth side of the display area DAA. In an embodiment, the second pad portion PDA2 may be disposed on an opposite side of the display area DAA in the second direction DR2, for example. The second pad portion PDA2 may be disposed outside the second distribution circuit 720 in the second direction DR2. That is, as shown in FIG. 4, the second pad portion PDA2 may be disposed closer to the edge of the display panel 100 than the second distribution circuit 720.

The first distribution circuit 710 distributes data voltages applied through the first pad portion PDA1 to the plurality of data lines DL. In an embodiment, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced, for example. The first distribution circuit 710 may be disposed on the third side of the display area DAA of the display panel 100. In an embodiment, the first distribution circuit 710 may be disposed on one side of the display area DAA in the second direction DR2, for example. That is, as shown in FIG. 4, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may inspect the operation of each of the pixels PX in the display area DAA. The second distribution circuit 720 may be disposed on the fourth side of the display area DAA of the display panel 100. In an embodiment, the second distribution circuit 720 may be disposed on an opposite side of the display area DAA in the second direction DR2, for example. That is, as shown in FIG. 4, the second distribution circuit 720 may be disposed on the upper side of the display area DAA.

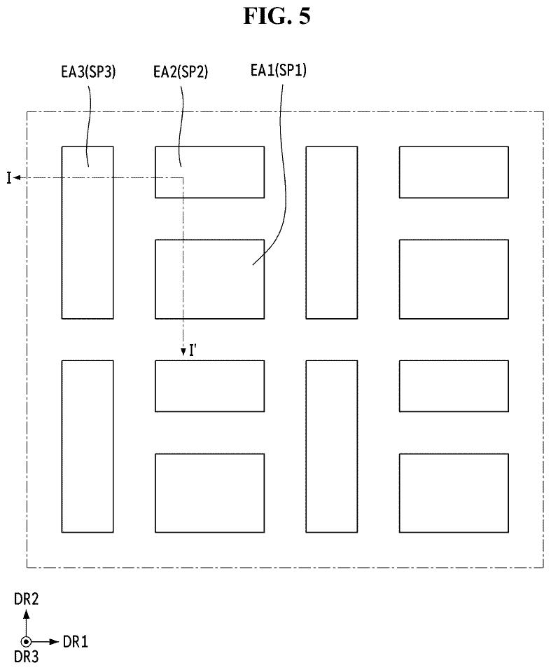

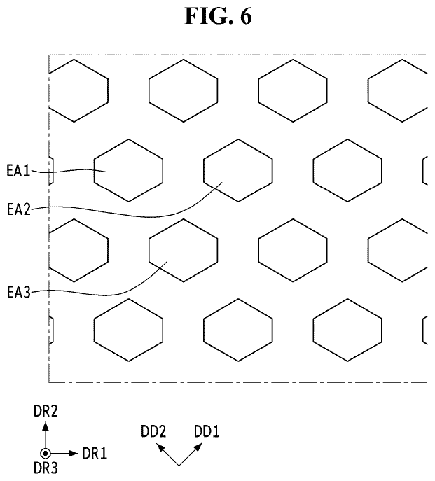

FIG. 5 is a schematic plan view illustrating an embodiment of the display area shown in FIG. 4. FIG. 6 is a schematic plan view illustrating another embodiment of the display area shown in FIG. 4.

Referring to FIG. 5, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. In an embodiment, the first sub-pixel SP1 may include the first emission area EA1, the second sub-pixel SP2 may include the second emission area EA2, and the third sub-pixel SP3 may include the third emission area EA3, for example.

Each of the first emission area EA1, the second emission area EA2, and the third emission area EA3 may be an area defined by a pixel defining film PDL (refer to FIG. 7). In an embodiment, each of the first emission area EA1, the second emission area EA2, and the third emission area EA3 may be an area defined by a first pixel defining film PDL1 (refer to FIG. 7), for example.

The length of the third emission area EA3 in the first direction DR1 may be less than the length of the first emission area EA1 in the first direction DR1, and the length of the second emission area EA2 in the first direction DR1. The length of the first emission area EA1 in the first direction DR1 and the length of the second emission area EA2 in the first direction DR1 may be substantially the same.

The length of the third emission area EA3 in the second direction DR2 may be greater than the length of the first emission area EA1 in the second direction DR2, and the length of the second emission area EA2 in the second direction DR2. The length of the first emission area EA1 in the second direction DR2 may be greater than the length of the second emission area EA2 in the second direction DR2.

In each of the plurality of pixels PX, the first emission area EA1 and the second emission area EA2 may be next (adjacent) to each other in the second direction DR2. Further, the first emission area EA1 and the third emission area EA3 may be next (adjacent) to each other in the first direction DR1. Further, the second emission area EA2 and the third emission area EA3 may be next (adjacent) to each other in the first direction DR1. The area of the first emission area EA1, the area of the second emission area EA2, and the area of the third emission area EA3 may be different from each other.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. In an embodiment, the blue wavelength band may be a wavelength band of light whose main peak wavelength is in the range of about 370 nanometers (nm) to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm, for example.

In another embodiment, as shown in FIG. 6, the first emission area EA1, the second emission area EA2, and the third emission area EA3 may be disposed in a hexagonal structure having a hexagonal shape in a plan view. In this case, the first emission area EA1 and the second emission area EA2 may be next (adjacent) to each other in the first direction DR1, but the second emission area EA2 and the third emission area EA3 may be next (adjacent) to each other in a first diagonal direction DD1, and the first emission area EA1 and the third emission area EA3 may be next (adjacent) to each other in a second diagonal direction DD2.

Although it is illustrated in FIGS. 5 and 6 that each of the plurality of pixels PX includes the three emission areas EA1, EA2, and EA3, the disclosure is not limited thereto. That is, each of the plurality of pixels PX may include four emission areas. Further, each of the emission areas EA1, EA2, and EA3 may have a polygonal, circular, elliptical, or atypical shape in a plan view, unlike those shown in FIGS. 5 and 6.

The arrangement of the emission areas EA1, EA2, and EA3 of the plurality of pixels PX is not limited to that illustrated in FIGS. 5 and 6. In an embodiment, the emission areas of the plurality of pixels PX may be disposed in a stripe structure in which the emission areas are arranged in the first direction DR1, a PenTile® structure in which the emission areas are arranged in a diamond shape, or the like, for example.

FIG. 7 is a cross-sectional view illustrating an embodiment of the display panel taken along line I-I′ of FIG. 5.

Referring to FIG. 7, the display panel 100 may include a semiconductor backplane SBP, a light-emitting element backplane EBP, a display element layer EML, an encapsulation layer TFE, an adhesive layer APL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed at top surface portions of the semiconductor substrate SSUB. The plurality of well regions WA may be regions doped with a second type impurity. The second type impurity may be different from the aforementioned first type impurity. In an embodiment, when the first type impurity is a p-type impurity, the second type impurity may be an n-type impurity, for example. In an alternative embodiment, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on an opposite side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having an impurity concentration lower than that of the source region SA. The second low-concentration impurity region LDD2 may be a region having an impurity concentration lower than that of the drain region DA. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be disposed on the semiconductor substrate SSUB. The first semiconductor insulating film SINS1 may include or consist of silicon carbonitride (SiCN) or a silicon oxide (SiOx)-based inorganic film, but the disclosure is not limited thereto.

A second semiconductor insulating film SINS2 may be disposed on the first semiconductor insulating film SINS1. The second semiconductor insulating film SINS2 may include or consist of a silicon oxide (SiOx)-based inorganic film, but the embodiment of the specification is not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through contact plugs penetrating the first semiconductor insulating film SINS1 and the second semiconductor insulating film SINS2. The plurality of contact terminals CTE may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on side surfaces of the plurality of contact terminals CTE. The top surface of each of the plurality of contact terminals CTE may be exposed without being covered by the third semiconductor insulating film SINS3. The third semiconductor insulating film SINS3 may include or consist of a silicon oxide (SiOx)-based inorganic film, but the embodiment of the specification is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that may be bent or curved.

The light-emitting element backplane EBP may include a plurality of conductive layers ML1 to ML8, a plurality of vias VA1 to VA9, and a plurality of insulating films INS1 to INS9. The plurality of insulating films INS1 to INS9 may be used for electrical insulation between the plurality of conductive layers ML1 to ML8.

The first to eighth conductive layers ML1 to ML8 are connected to the plurality of contact terminals CTE exposed from the semiconductor backplane SBP, and serve to implement the circuit of the first sub-pixel SP1 shown in FIG. 3. In an embodiment, the first to sixth transistors T1 to T6 are merely formed in the semiconductor backplane SBP, and the connection of the first to sixth transistors T1 to T6 and the first and second capacitors C1 and C2 may be implemented by the first to eighth conductive layers ML1 to ML8, for example. In addition, the connection between the drain region corresponding to the drain electrode of the fourth transistor T4, the source region corresponding to the source electrode of the fifth transistor T5, and a first electrode AND of the light-emitting element LE (refer to FIG. 3) may also be implemented by the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and be connected to the first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and be connected to the second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and be connected to the third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and be connected to the fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and be connected to the fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and be connected to the sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and be connected to the seventh conductive layer ML7. Each of the eighth conductive layers ML8 may be disposed on the eighth insulating film INS8 and may be connected to the eighth via VA8.

The first to eighth conductive layers ML1 to ML8 may include or consist of substantially the same material as each other. The first to eighth conductive layers ML1 to ML8 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may include or consist of substantially the same material as each other. The first to eighth vias VA1 to VA8 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. First to eighth insulating films INS1 to INS8 may include or consist of a silicon oxide (SiOx)-based inorganic film, but the embodiment of the specification is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. In an embodiment, the thickness of the first conductive layer ML1 may be approximately 1360 angstroms (Å), for example. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. In an embodiment, the thickness of each of the seventh conductive layer ML7 and the eighth conductive layer ML8 may be approximately 9,000 Å, for example. The thickness of each of the seventh via VA7 and the eighth via VA8 may be approximately 6,000 Å.

A ninth insulating film INS9 may be disposed on the eighth insulating film INS8 and the eighth conductive layer ML8. The ninth insulating film INS9 may include or consist of a silicon oxide (SiOx)-based inorganic film, but the embodiment of the specification is not limited thereto.

Each of the ninth vias VA9 may penetrate the ninth insulating film INS9 and be connected to the eighth conductive layer ML8. The ninth vias VA9 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16,500 Å.

The display element layer EML may be disposed on the light-emitting element backplane EBP. The display element layer EML may include a reflective electrode layer RL, a tenth insulating film INS10, a tenth via VA10, light-emitting elements LE, and a pixel defining film PDL. Each of the light-emitting elements LE may include a first electrode AND, a light-emitting stack ES, and a second electrode CAT.

The reflective electrode layer RL may be disposed on the ninth insulating film INS9. The reflective electrode layer RL may include at least one reflective electrode RL1, RL2, RL3, and RL4, a first step layer STPL1, and a second step layer STPL2. In an embodiment, the reflective electrode layer RL may include first to fourth reflective electrodes RL1, RL2, RL3, and RL4 as shown in FIG. 7, for example.

Each of the first reflective electrodes RL1 may be disposed on the ninth insulating film INS9, and may be connected to the ninth via VA9. The first reflective electrodes RL1 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, the first reflective electrodes RL1 may include titanium nitride (TiN), for example.

Each of the second reflective electrodes RL2 may be disposed on the first reflective electrode RL1. The second reflective electrodes RL2 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, the second reflective electrodes RL2 may include aluminum (Al), for example.

The first step layer STPL1 may be disposed on the second reflective electrode RL2 in the second sub-pixel SP2 and the third sub-pixel SP3. The first step layer STPL1 may not be disposed on the second reflective electrode RL2 in the first sub-pixel SP1.

The second step layer STPL2 may be disposed on the first step layer STPL1 in the third sub-pixel SP3. The second step layer STPL2 may not be disposed on the second reflective electrode RL2 in the first sub-pixel SP1. In addition, the second step layer STPL2 may not be disposed on the first step layer STPL1 in the second sub-pixel SP2.

The thickness of the first step layer STPL1 may be set in consideration of the wavelength of the light of the second color and a distance from the light-emitting stack ES of the second sub-pixel SP2 to the fourth reflective electrode RL4 to advantageously reflect the light of the second color emitted from the light-emitting stack ES. The thickness of the second step layer STPL2 may be set in consideration of the wavelength of the light of the third color and a distance from the light-emitting stack ES of the third sub-pixel SP3 to the fourth reflective electrode RL4 to advantageously reflect the light of the third color emitted from the light-emitting stack ES.

The first step layer STPL1 and the second step layer STPL2 may include or consist of silicon carbonitride (SiCN) or a silicon oxide (SiOx)-based inorganic film, but the embodiment of the specification is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1 and the second reflective electrode RL2. In the third sub-pixel SP3, the third reflective electrode RL3 may be disposed on the second step layer STPL2 and the second reflective electrode RL2. The third reflective electrodes RL3 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, the third reflective electrodes RL3 may include titanium nitride (TiN), for example.

At least one of the first reflective electrode RL1, the second reflective electrode RL2, and the third reflective electrode RL3 may be omitted.

Each of the fourth reflective electrodes RL4 may be disposed on the third reflective electrode RL3. The fourth reflective electrodes RL4 may be a layer that reflects light from the light-emitting stack ES. The fourth reflective electrodes RL4 may include metal having relatively high reflectivity to advantageously reflect the light. In addition, since the fourth reflective electrode RL4 is an electrode that substantially reflects light from the light-emitting elements LE, the thickness of the fourth reflective electrode RL4 may be greater than the thickness of each of the first reflective electrode RL1, the second reflective electrode RL2, and the third reflective electrode RL3. The fourth reflective electrodes RL4 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, the fourth reflective electrodes RL4 may include aluminum (Al) or titanium (Ti), for example.

The tenth insulating film INS10 may be disposed on the ninth insulating film INS9 and the fourth reflective electrodes RL4. The tenth insulating film INS10 may be an optical auxiliary layer through which light reflected by the reflective electrode layer RL passes, among light emitted from the light-emitting elements LE. The tenth insulating film INS10 may include or consist of a silicon oxide (SiOx)-based inorganic film, but the disclosure is not limited thereto.

Each of the tenth vias VA10 may penetrate the tenth insulating film INS10 and be connected to the reflective electrode layer RL. The tenth vias VA10 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them.

The thicknesses of the tenth vias VA10 may be different in the first sub-pixel SP1, the second sub-pixel SP2, and the third sub-pixel SP3 in order to adjust a resonance distance of light emitted from the light-emitting elements LE in at least one of the first sub-pixel SP1, the second sub-pixel SP2, or the third sub-pixel SP3. In an embodiment, the thickness of the tenth via VA10 in the third sub-pixel SP3 may be less than the thickness of the tenth via VA10 in each of the first sub-pixel SP1 and the second sub-pixel SP2, for example. Further, the thickness of the tenth via VA10 in the second sub-pixel SP2 may be smaller than the thickness of the tenth via VA10 in the first sub-pixel SP1. That is, the distance between the light-emitting stack ES and the reflective electrode layer RL may be different in the first sub-pixel SP1, the second sub-pixel SP2, and the third sub-pixel SP3.

In summary, in order to adjust the distance between the light-emitting stack ES and the reflective electrode layer RL according to the main wavelength of light emitted from the first sub-pixel SP1, the second sub-pixel SP2, and the third sub-pixel SP3, the presence or absence of the first and second step layers STPL1 and STPL2 and the thickness of each of the first and second step layers STPL1 and STPL2 in the first sub-pixel SP1, the second sub-pixel SP2, and the third sub-pixel SP3 may be set.

The first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, the first electrode AND of each of the light-emitting elements LE may be titanium nitride (TiN), for example.

The pixel defining film PDL may be disposed on the tenth insulating film INS10 and a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3. That is, the pixel defining film PDL may define openings that partially expose the first electrode AND of each of the light-emitting elements LE.

The first emission area EA1 may be defined as an area in which the first electrode AND, the light-emitting stack ES, and the second electrode CAT are sequentially stacked in the first sub-pixel SP1 to emit light. The second emission area EA2 may be defined as an area in which the first electrode AND, the light-emitting stack ES, and the second electrode CAT are sequentially stacked in the second sub-pixel SP2 to emit light. The third emission area EA3 may be defined as an area in which the first electrode AND, the light-emitting stack ES, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the tenth insulating film INS10 and the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may include or consist of a silicon oxide (SiOx)-based inorganic film, but the embodiment of the specification is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. In an embodiment, the widths of the openings of the first pixel defining film PDL1 may be less than the widths of the openings of the second pixel defining film PDL2, and the widths of the openings of the second pixel defining film PDL2 may be less than the widths of the openings of the third pixel defining film PDL3, for example.

The light-emitting stack ES may include a first light-emitting stack ES1 disposed in the first emission area EA1, a second light-emitting stack ES2 disposed in the second emission area EA2, and a third light-emitting stack ES3 disposed in the third emission area EA3. Although not shown in detail, the first light-emitting stack ES1 may include a hole injecting layer (“HIL”), a hole transporting layer (“HTL”), a first light-emitting layer (“EML”), an electron transporting layer (“ETL”), and an electron injecting layer (“EIL”), the second light-emitting stack ES2 may include the HIL, the HTL, a second EML, the ETL, and the EIL, and the third light-emitting stack ES3 may include the HIL, the HTL, a third EML, the ETL, and the EIL.

In an embodiment, the HIL may be disposed on the first electrodes AND exposed by the openings of the pixel defining film PDL, the inner surfaces of the openings of the pixel defining film PDL, and the top surface of the pixel defining film PDL, for example. The HTL may be disposed on the HIL.

The first to third EMLs may be respectively disposed in the openings of the pixel defining film PDL on the HTL. The first EML may be disposed in the opening of the pixel defining film PDL in the first emission area EA1, and may emit light of a first color, e.g., red light. The second EML may be disposed in the opening of the pixel defining film PDL in the second emission area EA2, and may emit light of a second color, e.g., green light. The third EML may be disposed in the opening of the pixel defining film PDL in the third emission area EA3, and may emit light of a third color, e.g., blue light.

The ETL may be disposed on the first to third EMLs and the HTL, and the EIL may be disposed on the ETL.

In another embodiment, although not shown, a plurality of trenches (not shown) may be disposed between the first to third emission areas EA1, EA2, and EA3. The trenches may have a closed shape (e.g., a band shape such as a ring shape) respectively surrounding the first to third emission areas EA1, EA2, and EA3, and may be formed to penetrate the pixel defining film PDL. The HIL and the HTL formed on the first electrodes AND of the first to third emission areas EA1, EA2, and EA3 may be disconnected from each other by the trenches.

In another embodiment, the first to third light-emitting stacks ES1, ES2, and ES3 may be respectively disposed in the openings of the pixel defining film PDL, and may not be disposed on the pixel defining film PDL. In this case, the first to third light-emitting stacks ES1, ES2, and ES3 may be disconnected from each other by the pixel defining film PDL.

The second electrode CAT may be disposed on the first to third light-emitting stacks ES1, ES2, and ES3. The second electrode CAT may include or consist of a transparent conductive material (“TCO”) such as ITO or IZO that may transmit light or a semi-transmissive conductive material such as magnesium (Mg), silver (Ag), or an alloy of Mg and Ag. When the second electrode CAT includes or consists of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce or prevent oxygen or moisture from permeating into the display element layer EML. In an embodiment, the encapsulation layer TFE may include the first encapsulation inorganic film TFE1, and a second encapsulation inorganic film TFE2, for example.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxynitride (SiON), and silicon oxide (SiOx) are alternately stacked. The first encapsulation inorganic film TFE1 may be formed by a chemical vapor deposition (“CVD”) process.

The second encapsulation inorganic film TFE2 may be disposed on the first encapsulation inorganic film TFE1. The second encapsulation inorganic film TFE2 may include or consist of titanium oxide (TiOx) or aluminum oxide (AlOx), but the embodiment of the specification is not limited thereto. The second encapsulation inorganic film TFE2 may be formed by an atomic layer deposition (“ALD”) process. The thickness of the second encapsulation inorganic film TFE2 may be less than the thickness of the first encapsulation inorganic film TFE1.

The adhesive layer APL may be a layer for increasing the interfacial adhesion between the encapsulation layer TFE and the cover layer CVL. The adhesive layer APL may be an organic film such as acrylic resin, epoxy resin, phenolic resin, polyamide resin, or polyimide resin.

The cover layer CVL may be disposed on the adhesive layer APL. The cover layer CVL may be a glass substrate or a polymer resin. When the cover layer CVL is a glass substrate, it may be attached onto the adhesive layer APL, and may serve as an encapsulation substrate. When the cover layer CVL is a polymer resin, it may be directly applied onto the adhesive layer APL.

The polarizing plate POL may be disposed on the cover layer CVL. The polarizing plate POL may be a structure for reducing or preventing visibility degradation caused by reflection of external light. The polarizing plate POL may include a linear polarizing plate and a phase retardation film. In an embodiment, the phase retardation film may be a λ/4 plate (quarter-wave plate), for example, but the disclosure is not limited thereto.

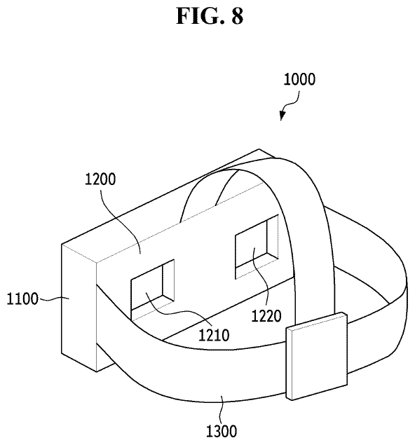

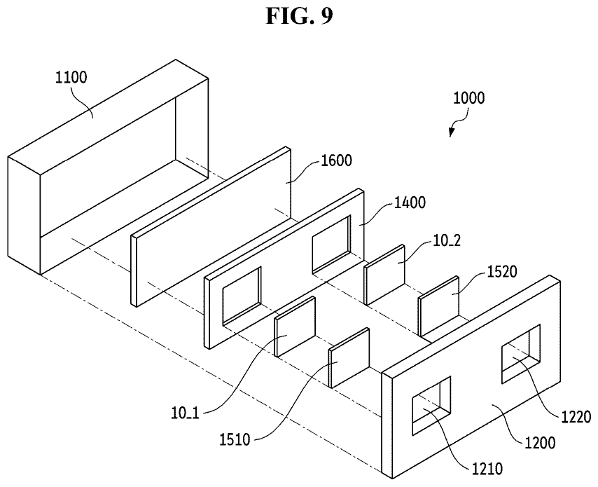

FIG. 8 is a schematic perspective view illustrating an HMD. FIG. 9 is a schematic exploded perspective view illustrating an embodiment of the HMD shown in FIG. 8.

Referring to FIGS. 8 and 9, an HMD 1000 in an embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 10_2 provides an image to the user's right eye. Since each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first and second display devices 10_1 and 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. In an alternative embodiment, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 8 and 9 illustrate that the first eyepiece 1210 and the second eyepiece 1220 are disposed separately, but the disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

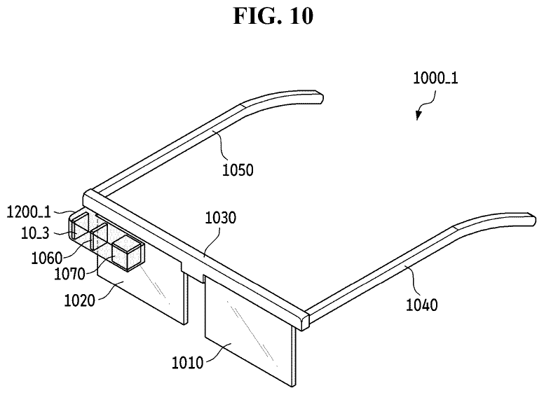

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1100 is implemented to be lightweight and compact, the HMD 1000 may be provided in the form of glasses as shown in FIG. 10.

In addition, the HMD 1000 may further include a battery for supplying power, an external memory slot for accommodating an external memory, and an external connection port and a wireless communication module for receiving an image source. The external connection port may be a universe serial bus (“USB”) terminal, a display port, or a high-definition multimedia interface (“HDMI”) terminal, and the wireless communication module may be a 5G communication module, a 4G communication module, a Wi-Fi module, or a Bluetooth® module.

FIG. 10 is a schematic perspective view illustrating another embodiment of a HMD.

Referring to FIG. 10, a HMD 1000_1 may be an eyeglasses-type display device in which a display device housing 1200_1 is implemented in a lightweight and compact manner. The HMD 1000_1 may include a display device 10_3, a left eye lens 1010, a right eye lens 1020, a support frame 1030, temples 1040 and 1050, an optical member 1060, an optical path conversion member 1070, and the display device housing 1200_1.

The display device housing 1200_1 may include the display device 10_3, the optical member 1060, and the optical path conversion member 1070. The image displayed on the display device 10_3 may be magnified by the optical member 1060, and may be provided to the user's right eye through the right eye lens 1020 after the optical path thereof is changed by the optical path conversion member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end of the support frame 1030, but the disclosure is not limited thereto. In an embodiment, the display device housing 1200_1 may be disposed at the left end of the support frame 1030, and in this case, the image of the display device 10_3 may be provided to the user's left eye, for example. In another embodiment, the display device housing 1200_1 may be disposed at both the left and right ends of the support frame 1030, and in this case, the user may view the image displayed on the display device 10_3 through both the left and right eyes.

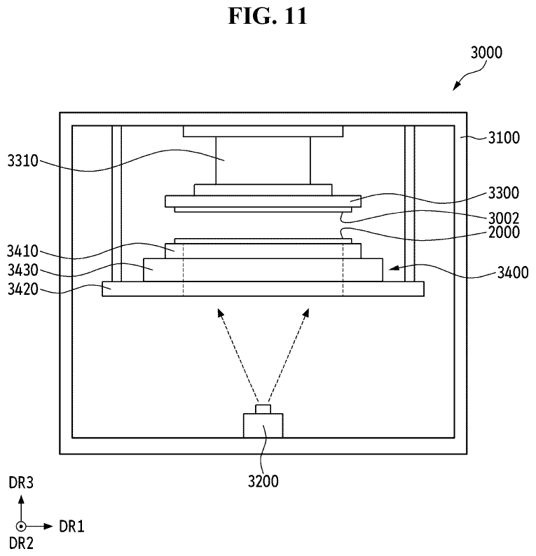

FIG. 11 is a schematic view illustrating an embodiment of a deposition mask and a deposition apparatus including the same according to the disclosure.

Referring to FIG. 11, a deposition apparatus 3000 may be used to form light emitting material layers on a backplane substrate 3002 in a manufacturing process of the display panel 100 (refer to FIG. 1). In an embodiment, as illustrated in FIG. 7, the semiconductor backplane SBP and the light-emitting element backplane EBP may be disposed on the backplane substrate 3002, and the reflective electrode layer RL and the insulating film INS10 may be disposed on the light-emitting element backplane EBP, for example. Electrode patterns, e.g., the anode electrodes AND may be disposed on the insulating film INS10, and the anode electrodes AND may be electrically connected to the reflective electrode layer RL through the vias VA10. The deposition apparatus 3000 may be used to form the light-emitting layers of the light emitting stacks ES1, ES2 and ES3 on the electrode patterns of the backplane substrate 3002.

The deposition apparatus 3000 may include a deposition source 3200 for providing a vapor deposition material on the backplane substrate 3002, a deposition mask 2000 disposed above the deposition source 3200, and a substrate chuck 3300 disposed above the deposition mask 2000 to support the backplane substrate 3002 such that the backplane substrate 3002 faces the deposition mask 2000. That is, the substrate chuck 3300 may support the backplane substrate 3002 such that a front surface of the backplane substrate 3002 faces downward, and may position the backplane substrate 3002 above the deposition mask 2000 to perform a deposition process.

The deposition source 3200, the deposition mask 2000, and the substrate chuck 3300 may be disposed in a process chamber 3100. The process chamber 3100 may have an internal space, and a deposition process for forming a deposition material layer on the backplane substrate 3002 may be performed in the internal space of the process chamber 3200. Although not shown, the process chamber 3100 may be connected to a vacuum pump (not shown), and the internal space of the process chamber 3100 may be set to a vacuum atmosphere by the vacuum pump. An opening (not shown) for the carry-in and carry-out of the backplane substrate 3002 and the deposition mask 2000 may be provided in a wall of the process chamber 3100, and the opening may be opened and closed by a gate valve (not shown).

A deposition material may be accommodated in the deposition source 3200. The deposition source 3200 may evaporate the deposition material such as an organic material, an inorganic material, a conductive material, or the like toward the backplane substrate 3002, and the evaporated deposition material may be deposited on the backplane substrate 3002 through the deposition mask 2000. In an embodiment, the deposition source 3200 may evaporate an organic material for forming light emitting material layers on the backplane substrate 3002, and the evaporated organic material may be deposited on the electrode patterns on the backplane substrate 3002 through the deposition mask 2000, for example.

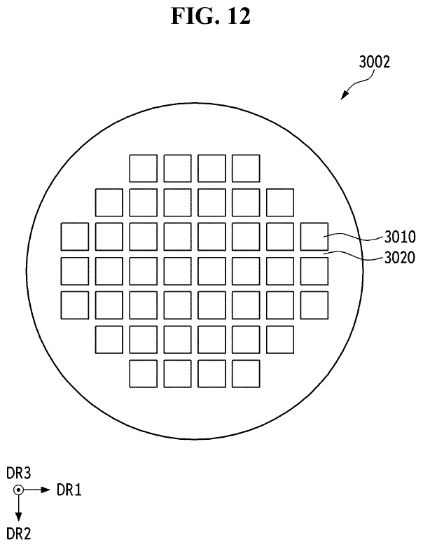

FIG. 12 is a schematic bottom view illustrating the backplane substrate as shown in FIG. 11.

Referring to FIG. 12, the backplane substrate 3002 may include a plurality of display cell regions 3010 and a scribe lane region 3020 disposed between the display cell regions 3010. The display cell regions 3010 may be arranged in a matrix form along the first direction DR1 and the second direction DR2 as illustrated in FIG. 12, and each of the display cell regions 3010 may be individualized into a plurality of display panels 100 (refer to FIG. 1) by a dicing process after the display manufacturing process is completed. In an embodiment, the first direction DR1 may be a first horizontal direction, and the second direction DR2 may be a second horizontal direction perpendicular to the first direction DR1, for example.

Each of the display cell regions 3010 may include the semiconductor backplane SBP, the light-emitting element backplane EBP disposed on the semiconductor backplane SBP, the reflective electrode layer RL disposed on the light-emitting element backplane EBP, and the insulating film INS10 disposed on the reflective electrode layer RL. In addition, each of the display cell regions 3010 may include the plurality of electrode patterns, e.g., the plurality of anode electrodes AND disposed on the insulating film INS10, and the anode electrodes AND may be connected to the reflective electrode layer RL through the plurality of vias VA10. In this case, the electrode patterns of the display cell regions 3010 may be disposed on the front surface of the backplane substrate 3002, and the substrate chuck 3300 may hold a rear surface of the backplane substrate 3002 such that the electrode patterns of the display cell regions 3010 face downward, i.e., face the deposition source 3200.

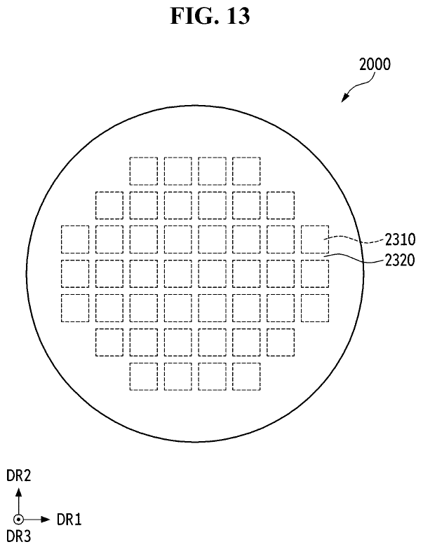

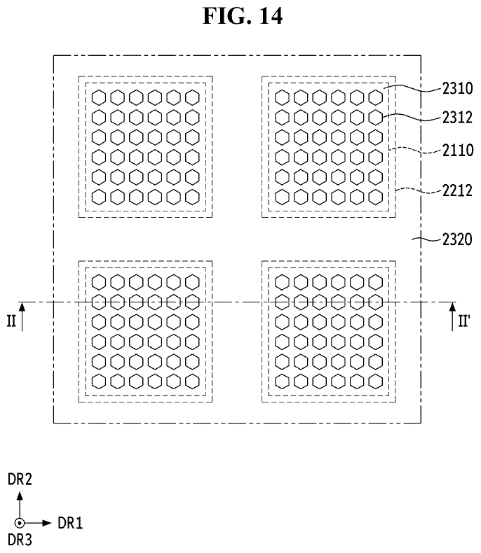

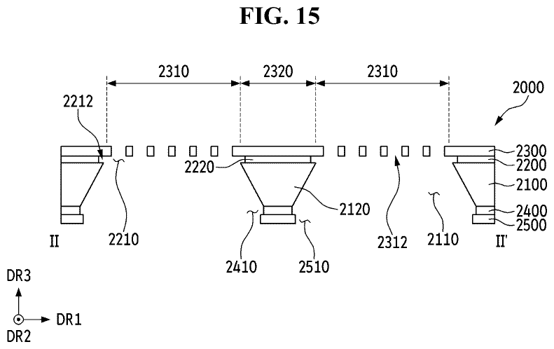

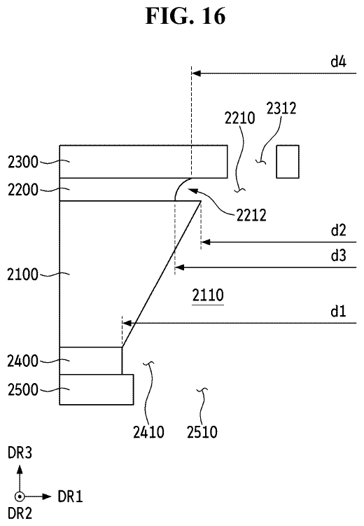

FIG. 13 is a schematic plan view illustrating the deposition mask as shown in FIG. 11. FIG. 14 is a schematic enlarged plan view illustrating mask cell regions as shown in FIG. 13. FIG. 15 is a schematic cross-sectional view taken along line II-II′ as shown in FIG. 14. FIG. 16 is a schematic enlarged cross-sectional view illustrating an intermediate inorganic film as shown in FIG. 15.

Referring to FIGS. 13 to 16, the deposition mask 2000 may include mask cell regions 2310 respectively corresponding to the display cell regions 3010 of the backplane substrate 3002. Each of the mask cell regions 2310 may define a plurality of pixel openings 2312 exposing the anode electrodes AND in the deposition process. In an embodiment, the deposition mask 2000 may include a mask frame 2100, an intermediate inorganic film 2200 disposed on the mask frame 2100, and a membrane 2300 disposed on the intermediate inorganic film 2200, for example. In this case, the membrane 2300 may include a plurality of mask cell regions 2310, and each of the mask cell regions 2310 may have a plurality of pixel openings 2312.

In an embodiment, the mask frame 2100 may define cell openings 2110 and include a first rib region 2120 defining the cell openings 2110, for example. The intermediate inorganic film 2200 may define intermediate openings 2210 defined on the cell openings 2110 and include a second rib region 2220 defining the intermediate openings 2210. The membrane 2300 may include mask cell regions 2310 respectively disposed on the intermediate openings 2210, and a grid region 2320 disposed between the mask cell regions 2310. That is, the second rib region 2220 of the intermediate inorganic film 2200 may be disposed on the first rib region 2120 of the mask frame 2100, and the grid region 2320 of the membrane 2300 may be disposed on the second rib region 2220 of the intermediate inorganic film 2200. In addition, the mask cell regions 2310 may be exposed toward the deposition source 3200 through the intermediate openings 2210 and the cell openings 2110, and the pixel openings 2312 may penetrate the mask cell regions 2310 to be extended to the intermediate openings 2210.

As shown in FIG. 13, the mask cell regions 2310 may be arranged in a matrix form along the first direction DR1 and the second direction DR2. In an embodiment, the mask cell regions 2310 may be arranged in a matrix form along the first horizontal direction and the second horizontal direction perpendicular to the first horizontal direction, and may be arranged to respectively correspond to the display cell regions 3010 of the backplane substrate 3002, for example.

The intermediate inorganic film 2200 and the membrane 2300 may be disposed on a front surface of the mask frame 2100, and a first rear inorganic film 2400 and a second rear inorganic film 2500 may be disposed on a rear surface of the mask frame 2100. The first rear inorganic film 2400 and the second rear inorganic film 2500 may define first rear openings 2410 and second rear openings 2510 communicating with the cell openings 2110, respectively, and may function as an etching mask in an etching process for defining the cell openings 2110.

As one of the embodiments, the intermediate inorganic film 2200 may include or consist of the same material as that of the first rear inorganic film 2400, and the membrane 2300 may include or consist of the same material as that of the second rear inorganic film 2500. In particular, the intermediate inorganic film 2200 may include or consist of a material having etching selectivity with respect to the membrane 2300 and the mask frame 2100. In an embodiment, the intermediate inorganic film 2200 may include or consist of silicon oxide (SiOx), and the membrane 2300 may include or consist of silicon nitride (SiNx). The mask frame 2100 may include or consist of single crystal silicon (Si), for example.

The cell openings 2110 of the mask frame 2100 may be defined to expose the intermediate inorganic film 2200 through an anisotropic etching process using the first rear inorganic film 2400 and the second rear inorganic film 2500 as an etching mask. In an embodiment, a single crystal silicon substrate may be used as the mask frame 2100, and the cell openings 2110 may be defined by a wet etching process using tetramethyl ammonium hydroxide (“TMAH”), or potassium hydroxide (“KOH”), for example. In this case, the <100>crystal direction of the single crystal silicon substrate used as the mask frame 2100 may be the third direction DR3, and, accordingly, the cell openings 2110 may be defined by the wet etching process to have a width that gradually decreases from the rear surface of the mask frame 2100 toward the membrane 2300, i.e., in the third direction DR3. In an embodiment, each of inner surfaces of the cell openings 2110 may be formed to have an inclination of about 54.74° with respect to the rear surface of the mask frame 2100, for example. That is, as illustrated in FIGS. 15 and 16, a lower width d1 of each of the cell openings 2110 may be greater than an upper width d2 of each of the cell openings 2110.

Referring to FIG. 16, the intermediate opening 2210 of the intermediate inorganic film 2200 may have a width greater than that of the cell opening 2110. In particular, the intermediate opening 2210 of the intermediate inorganic film 2200 may have a width greater than the upper width d2 of the cell opening 2110. Accordingly, a groove 2212 (refer to FIG. 14) having a band shape may be defined between the mask frame 2100 and the membrane 2300, and an upper edge of the cell opening 2110 may be spaced apart from the membrane 2300 by as much as the thickness of the intermediate inorganic film 2200. In the disclosure, the term “band shape” may include at least one of curved portion and a strait portion in a plan view.

The intermediate opening 2210 may be defined by a wet etching process after the cell opening 2110 is defined. In an embodiment, when the intermediate inorganic film 2200 includes or consists of silicon oxide (SiOx), the intermediate opening 2210 may be defined by a wet etching process using buffered oxide etchant (“BOE”) or diluted HF, for example. In this case, as illustrated in FIG. 16, a lower width d3 of the intermediate opening 2210 may be greater than the upper width d2 of the cell opening 2110, and an upper width d4 of the intermediate opening 2210 may be smaller than the lower width d3 of the intermediate opening 2210.

A deposition material layer may also be formed on the deposition mask 2000 while deposition material layers are formed on the backplane substrate 3002 by the deposition mask 2000, and the deposition material layer on the deposition mask 2000 may be removed by an ultrasonic cleaning process. In an embodiment, an ultrasonic cleaning process using an N-methyl-2-pyrrolidone (“NMP”) cleaning solution may be performed, and ultrasonic vibration may be applied to the deposition mask 2000 during the ultrasonic cleaning process, for example.

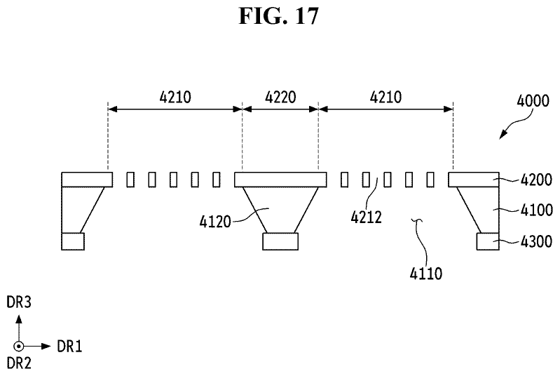

FIG. 17 is a schematic cross-sectional view illustrating a conventional deposition mask.

Referring to FIG. 17, a conventional deposition mask 4000 may include a mask frame 4100 and a membrane 4200 disposed on the mask frame 4100. The mask frame 4100 may define cell openings 4110, and may include a rib region 4120 defining the cell openings 4110. The membrane 4200 may include mask cell regions 4210 disposed on the cell openings 4110 and a grid region 4220 disposed on the rib region 4120. The mask cell regions 4210 may define pixel openings 4212 communicating with the cell openings 4110, and a rear inorganic film 4300 may be disposed on a rear surface of the mask frame 4100.

A single crystal silicon substrate may be used as the mask frame 4100, and the membrane 4200 and the rear inorganic film 4300 may include or consist of silicon nitride. In particular, the cell openings 4110 may be defined by a wet etching process using TMAH or KOH, and thus the cell openings 4110 may have a width that gradually decreases from the rear surface of the mask frame 4100 toward the membrane 4200.

When an ultrasonic cleaning process is performed on the conventional deposition mask 4000, the mask frame 4100 and the membrane 4200 may be damaged due to ultrasonic vibration. Damage to the mask frame 4100 and the membrane 4200 may be caused by a difference in natural frequency between the mask frame 4100 and the membrane 4200, and vibration of the mask cell regions 4210 caused by the ultrasonic vibration. In particular, the interface between an upper edge of the cell opening 4110 and an edge of the mask cell region 4210 may be the most structurally vulnerable portion, and, as a result, the upper edge of the cell opening 4110, that is, the upper edge of the rib region 4120, and the edge of the mask cell region 4210 may be damaged by the ultrasonic vibration during the ultrasonic cleaning process.

However, according to the disclosure, as shown in FIG. 16, the groove 2212 of the intermediate opening 2210 may allow an upper edge of the cell opening 2110 and an edge of the mask cell region 2310 to be spaced apart from each other by as much as the thickness of the intermediate inorganic film 2200, so that damage to the upper edge of the cell opening 2110 and the edge of the mask cell region 2310 may be prevented during the ultrasonic cleaning process.

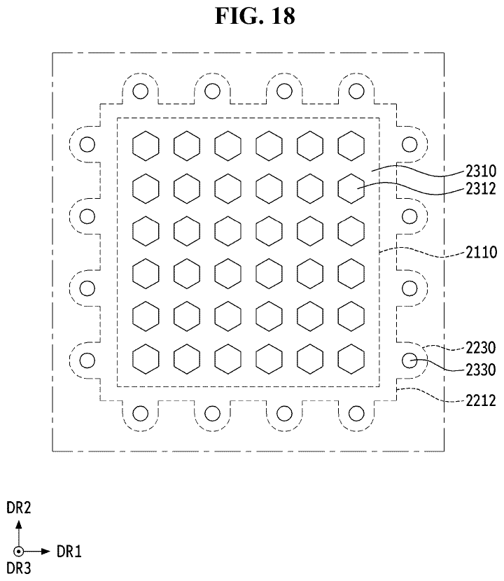

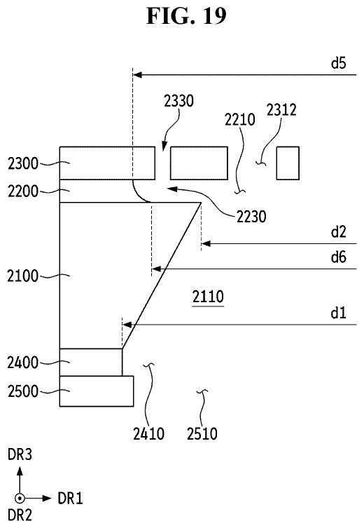

FIG. 18 is a plan view illustrating another embodiment of a deposition mask according to the disclosure. FIG. 19 is a schematic enlarged cross-sectional view illustrating recesses as shown in FIG. 18.

Referring to FIGS. 18 and 19, the intermediate inorganic film 2200 may define a plurality of recesses 2230 arranged along a circumference of the intermediate opening 2210 and extended to the intermediate opening 2210. Specifically, the plurality of recesses 2230 may be arranged in a band shape surrounding the intermediate opening 2210, and may be extended to the groove 2212 of the intermediate opening 2210. In particular, the plurality of recesses 2230 may be used to expand the width of the intermediate opening 2210, and, as a result, damage to the mask frame 2100 and the membrane 2300 may be sufficiently prevented during the ultrasonic cleaning of the deposition mask 2000.

The plurality of recesses 2230 may be defined simultaneously with the intermediate opening 2210 through a wet etching process. In an embodiment, the membrane 2300 may be provided with a plurality of through holes 2330 arranged in a band shape surrounding the mask cell region 2310, for example. The through holes 2330 may be respectively defined on the recesses 2230 of the intermediate inorganic film 2200 and respectively extended to the recesses 2230 of the intermediate inorganic film 2200. The through holes 2330 may be defined simultaneously with the pixel openings 2312, and may function as passages for providing an etchant in the wet etching process for defining the intermediate opening 2210. That is, the plurality of recesses 2230 may be defined by the etchant provided through the through holes 2330, and the recesses 2230 may be extended to the groove 2212 of the intermediate opening 2210 during the wet etching process. In this case, as illustrated in FIG. 19, an upper width d5 of the recesses 2230 may be greater than a lower width d6 of the recesses 2230.

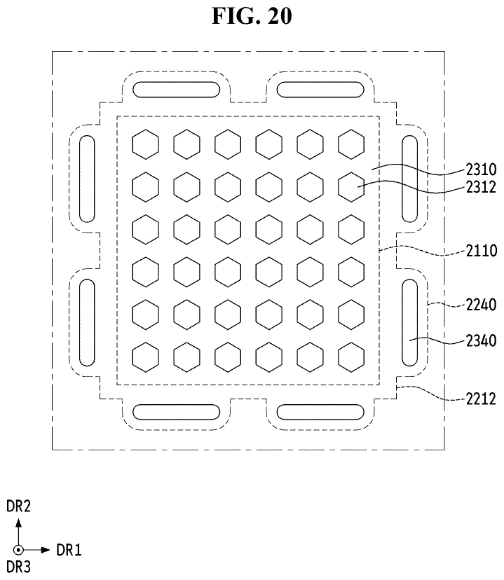

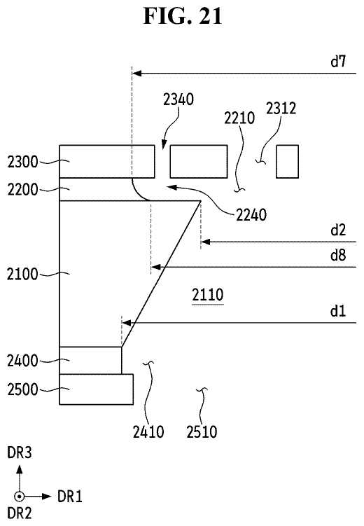

FIG. 20 is a schematic plan view illustrating another embodiment of a deposition mask according to the disclosure. FIG. 21 is a schematic enlarged cross-sectional view illustrating a recess shown in FIG. 20.

Referring to FIGS. 20 and 21, the intermediate inorganic film 2200 may define a plurality of recesses 2240 arranged along the circumference of the intermediate opening 2210 and extended to the intermediate opening 2210. To elaborate, the plurality of recesses 2240 may be arranged in a band shape surrounding the intermediate opening 2210, and may be extended to the groove 2212 of the intermediate opening 2210. Also, the plurality of recesses 2240 may extend along the circumference of the intermediate opening 2210, i.e., the circumference of the groove 2212.

The plurality of recesses 2240 may be defined simultaneously with the intermediate opening 2210 through a wet etching process. In an embodiment, the membrane 2300 may be provided with a plurality of through slots 2340 arranged in a band shape surrounding the mask cell region 2310, and the plurality of through slots 2340 may extend in the same direction as that of the recesses 2240, for example. In addition, the through slots 2340 may be respectively defined on the recesses 2240 of the intermediate inorganic film 2200 and respectively extended to the recesses 2240 of the intermediate inorganic film 2200. The through slots 2340 may be defined simultaneously with the pixel openings 2312, and may function as passages for providing an etchant in the wet etching process for defining the intermediate opening 2210. That is, the plurality of recesses 2240 may be defined by the etchant provided through the through slots 2340, and the recesses 2240 may be extended to the groove 2212 of the intermediate opening 2210 during the wet etching process. In this case, as illustrated in FIG. 21, an upper width d7 of the recesses 2240 may be greater than a lower width d8 of the recesses 2240.

Referring back to FIG. 11, the substrate chuck 3300 may be disposed above the deposition source 3200 and may support the backplane substrate 3002, allowing the backplane substrate 3002 to face the deposition source 3200. In an embodiment, the substrate chuck 3300 may be an electrostatic chuck configured to hold the rear surface of the backplane substrate 3002 using an electrostatic force, for example. Specifically, the first electrodes (also referred to as anode patterns) AND may be arranged on the front surface of the backplane substrate 3002, and the substrate chuck 3300 may hold the rear surface of the backplane substrate 3002 such that the front surface of the backplane substrate 3002 faces the deposition source, i.e., faces downward.

Although not shown, the backplane substrate 3002 may be loaded into the process chamber 3100 by a transfer robot, and lift fingers (not shown) for transferring the backplane substrate 3002 from the transfer robot to the substrate chuck 3300 may be disposed in the process chamber 3100. In an embodiment, the backplane substrate 3002 may be placed on the lift fingers after being brought into the process chamber 3100 by the transfer robot, and the lift fingers may be raised to load the backplane substrate 3002 on the substrate chuck 3300, for example. Subsequently, the substrate chuck 3300 may hold the rear surface of the backplane substrate 3002 by the electrostatic force.

An upper driving unit 3310 for moving and rotating the substrate chuck 3300 may be disposed above the substrate chuck 3300 to adjust the position and angle of the backplane substrate 3002. In an embodiment, the upper driving unit 3310 may move the substrate chuck 3300 in the first and second directions DR1 and DR2 to adjust the horizontal position of the backplane substrate 3002, and may move the substrate chuck 3300 in the third direction DR3 to adjust the vertical position of the backplane substrate 3002, for example. In this case, the first direction DR1, the second direction DR2, and the third direction DR3 may be an X-axis direction, a Y-axis direction, and a Z-axis direction, respectively.

In addition, the upper driving unit 3310 may rotate the substrate chuck 3300 around the Z-axis to adjust the azimuthal angle of the backplane substrate 3002. Further, in order to adjust the inclination of the backplane substrate 3002, the upper driving unit 3310 may rotate the substrate chuck 3300 around the X-axis, and may rotate the substrate chuck 3300 around the Y-axis. In an embodiment, the upper driving unit 3310 may include a hexapod actuator that provides a motion of 6 degrees of freedom (X, Y, Z, θx, θy, and θz), for example.

A mask stage 3400 on which the deposition mask 2000 is placed may be disposed above the deposition source 3200. That is, the mask stage 3400 may be disposed under the substrate chuck 3300 and may support an edge portion of the deposition mask 2000. The deposition mask 2000 may be carried into the process chamber 3100 by the transfer robot. In an embodiment, the deposition mask 2000 brought into the process chamber 3100 by the transfer robot may be placed on the lift fingers, and the lift fingers may be lowered to load the deposition mask 2000 on the mask stage 3400, for example.

The mask stage 3400 may include a mask chuck 3410 for supporting the deposition mask 2000. Although not shown in detail, the mask chuck 3410 may have a circular ring shape to support the edge portion of the deposition mask 2000. In an embodiment, the mask chuck 3410 may be an electrostatic chuck configured to hold the edge portion of the deposition mask 2000 using an electrostatic force, for example.

The mask stage 3400 may include a support plate 3420 for supporting the mask chuck 3410. The support plate 3420 may define an opening to allow the mask cell regions 2310 of the deposition mask 2000 to be exposed toward the deposition source 3200, and a lower driving unit 3430 for adjusting the position and angle of the deposition mask 2000 may be disposed between the support plate 3420 and the mask chuck 3410. In an embodiment, the lower driving unit 3430 may move the mask chuck 3410 in the first and second directions DR1 and DR2 to adjust the horizontal position of the deposition mask 2000, and may rotate the mask chuck 3410 around the Z-axis to adjust the azimuthal angle of the deposition mask 2000, for example. In an embodiment, the lower driving unit 3430 may include a piezo actuator that provides a motion of 3 degrees of freedom (X, Y, and θz), and the piezo actuator may have a quadrilateral band shape.

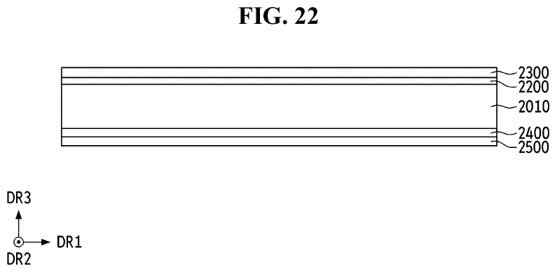

FIGS. 22 to 26 are schematic cross-sectional views illustrating another embodiment of a method of manufacturing a deposition mask according to the disclosure.

Referring to FIG. 22, the intermediate inorganic film 2200 may be formed on a mask substrate (also referred as a substrate) 2010. In an embodiment, a single crystal silicon substrate may be used as the mask substrate 2010, and the mask substrate 2010 may function as the mask frame 2100 of the deposition mask 2000, for example. In an embodiment, the intermediate inorganic film 2200 may include or consist of silicon oxide (SiOx), and may be formed to have a thickness of about 0.5 micrometer (μm) to about 2 μm on the mask substrate 2010 through a thermal oxidation process, for example.

Subsequently, the membrane 2300 may be formed on the intermediate inorganic film 2200. In an embodiment, the membrane 2300 may include or consist of silicon nitride (SiNx), and may be formed to have a thickness of about 0.5 μm to about 3 μm on the intermediate inorganic film 2200 through a thermal chemical vapor deposition (“TCVD”) process, for example. The membrane 2300 may be formed by a reaction between a first source gas including or consisting of silicon and a second source gas including or consisting of nitrogen. By way of non-limiting example, dichlorosilane (SiH₂Cl₂) gas may be used as the first source gas, and ammonia (NH₃) gas may be used as the second source gas.

The intermediate inorganic film 2200 and the membrane 2300 may be formed on the front surface of the mask substrate 2010, and the first rear inorganic film 2400 and the second rear inorganic film 2500 may be formed on the rear surface of the mask substrate 2010. As one of the embodiments, the first rear inorganic film 2400 may be formed simultaneously with the intermediate inorganic film 2200, and the second rear inorganic film 2500 may be formed simultaneously with the membrane 2300. That is, the first rear inorganic film 2400 may include or consist of the same material as that of the intermediate inorganic film 2200, and the second rear inorganic film 2500 may include or consist of the same material as that of the membrane 2300.

In another embodiment, the operation of forming the first rear inorganic film 2400 may be omitted. In this case, the intermediate inorganic film 2200 may be formed on the front surface of the mask substrate 2010 through a CVD process or a sputtering process, and then, the membrane 2300 and the second rear inorganic film 2500 may be formed on the front surface and the rear surface of the mask substrate 2010, respectively.

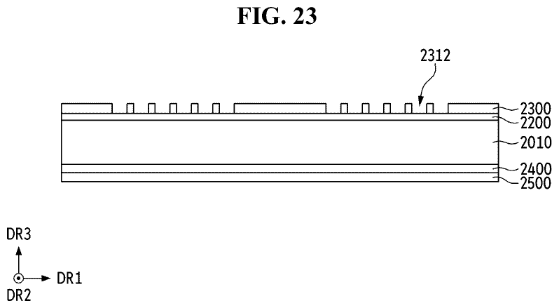

Referring to FIG. 23, the membrane 2300 may be patterned to define the plurality of pixel openings 2312 that expose the intermediate inorganic film 2200. In an embodiment, after forming on the membrane 2300 a first photoresist pattern (not shown) exposing the portions where the pixel openings 2312 are to be defined, an etching process using the first photoresist pattern as an etching mask may be performed to define the pixel openings 2312 that expose the intermediate inorganic film 2200, for example. In an embodiment, the pixel openings 2312 may be defined by a reactive ion etching (“RIE”) process using a reaction gas such as CHF₃, CH₃F, CH₂F₂, CHF₆, CF₄, C₂F₆, C₃F₆, or the like and a sputtering gas such as Ar, O₂/Ar, or the like, for example. In this case, an inductively coupled plasma (“ICP”) source or a capacitively coupled plasma (“CCP”) source may be used as a plasma source. In particular, by appropriately controlling flow rates of the reactive gas and the sputtering gas, an internal temperature of the process chamber, radio frequency (“RF”) power for plasma formation, bias power applied to a chuck on which the mask substrate 2010 is placed, or the like, the pixel openings 2312 may be defined to have a constant width in a thickness direction of the membrane 2300. The first photoresist pattern may be removed through a stripping and/or ashing process after the pixel openings 2312 are defined.

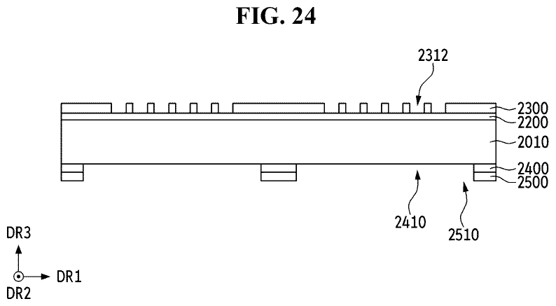

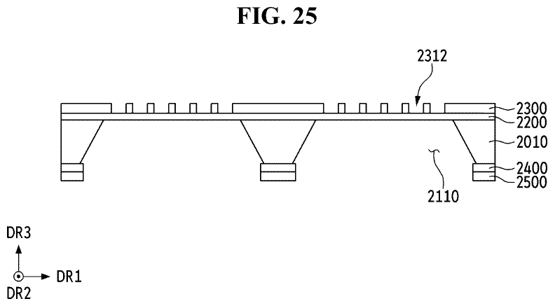

Referring to FIGS. 24 and 25, the mask substrate 2010 may be patterned to define the cell openings 2110 that expose the intermediate inorganic film 2200. In an embodiment, after forming on the second rear inorganic film 2500 a second photoresist pattern (not shown) exposing the portions where the cell openings 2110 are to be defined, an anisotropic etching process, such as an RIE process, may be performed using the second photoresist pattern as an etching mask, for example. The anisotropic etching process may be performed until rear portions of the mask substrate 2010, i.e., portions where the cell openings 2110 are to be defined, are exposed, and, as a result, the first rear openings 2410 and the second rear openings 2510 penetrating the first rear inorganic film 2400 and the second rear inorganic film 2500 may be defined, as shown in FIG. 24. The second photoresist pattern may be removed through a stripping and/or ashing process after the first rear openings 2410 and the second rear openings 2510 are defined.

Referring to FIG. 25, the mask substrate 2010 may be partially removed to expose the intermediate inorganic film 2200 through a wet etching process using the first rear inorganic film 2400 and the second rear inorganic film 2500 as an etching mask, thereby defining the plurality of cell openings 2110. In an embodiment, the wet etching process may be performed using an etchant including or consisting of TMAH or KOH, for example. In this case, the <100> crystal direction of the single crystal silicon substrate used as the mask substrate 2010 may be the third direction DR3, and, accordingly, the cell openings 2110 may be defined to have a width that gradually decreases from the rear surface of the mask substrate 2010 toward the membrane 2300, i.e., in the third direction DR3, by the wet etching process. In an embodiment, each of the inner surfaces of the cell openings 2110 may be defined to have an inclination of about 54.74° with respect to the rear surface of the mask substrate 2010, for example. As a result, as illustrated in FIG. 16, the lower width d1 of each of the cell openings 2110 may be greater than the upper width d2 of each of the cell openings 2110.

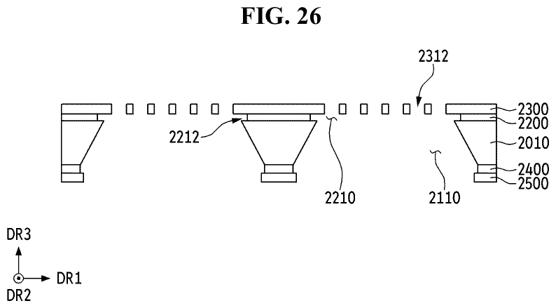

Referring to FIG. 26, the intermediate inorganic film 2200 may be patterned to define the intermediate openings 2210 extending to the pixel openings 2312 and the cell openings 2110. In particular, each of the intermediate openings 2210 may have a width greater than the upper width of the cell openings 2110 such that the groove 2212 having a band shape is defined between the mask substrate 2010 and the membrane 2300, and accordingly, the upper edges of the cell openings 2110 may be spaced apart from the membrane 2300 by as much as the thickness of the intermediate inorganic film 2200.

The intermediate openings 2210 may be defined by a wet etching process. As one of the embodiments, when the intermediate inorganic film 2200 includes or consists of silicon oxide (SiOx), the intermediate openings 2210 may be defined by a wet etching process using BOE or diluted HF. In this case, as illustrated in FIG. 16, the lower width d3 of the intermediate openings 2210 may be greater than the upper width d2 of the cell openings 2110, and the upper width d4 of the intermediate openings 2210 may be smaller than the lower width d3 of the intermediate openings 2210.

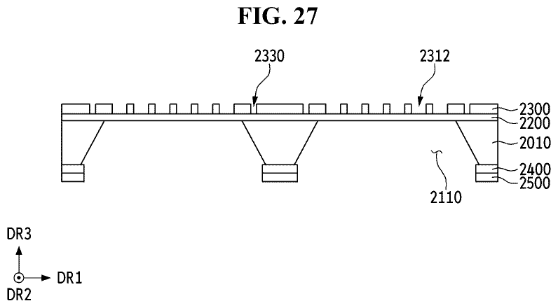

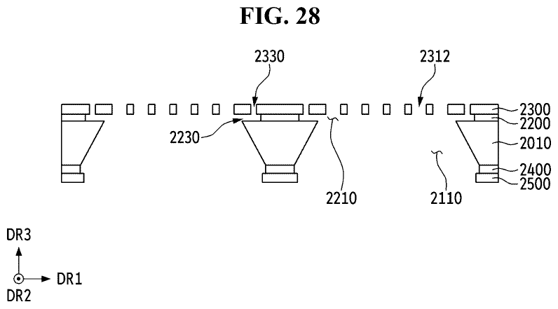

FIGS. 27 and 28 are schematic cross-sectional views illustrating another embodiment of a method of manufacturing a deposition mask according to the disclosure.

Referring to FIG. 27, the membrane 2300 may be patterned to define the pixel openings 2312 and the through holes 2330 exposing the intermediate inorganic film 2200. As shown in FIG. 18, the through holes 2330 may be arranged in a band shape surrounding the plurality of pixel openings 2312, that is, in a band shape surrounding the mask cell region 2310, and may be defined simultaneously with the pixel openings 2312. In an embodiment, after forming on the membrane 2300 a photoresist pattern (not shown) that exposes portions where the pixel openings 2312 and the through holes 2330 are to be defined, an anisotropic etching process using this photoresist pattern as an etching mask may be performed to define the pixel openings 2312 and the through holes 2330 that expose the intermediate inorganic film 2200, for example.

After forming the pixel openings 2312 and the through holes 2330, the mask substrate 2010 may be patterned to define the plurality of cell openings 2110 exposing the intermediate inorganic film 2200. In the illustrated embodiment, the methods of forming the intermediate inorganic film 2200, the membrane 2300, the first rear inorganic film 2400, the second rear inorganic film 2500 and the cell openings 2110 are substantially the same as those described above with reference to FIGS. 22 to 25, and thus a detailed description thereof will be omitted here.

Referring to FIG. 28, the intermediate inorganic film 2200 may be patterned to define the intermediate openings 2210 extending to the pixel openings 2312 and the cell openings 2110 and the plurality of recesses 2230 arranged along the circumference of each of the intermediate openings 2210 and extended to the intermediate openings 2210. As one of the embodiments, the intermediate openings 2210 and the recesses 2230 may be defined simultaneously through a wet etching process, and the through holes 2330 may serve as passages for providing an etchant during the wet etching process. That is, the plurality of recesses 2230 may be defined by the etchant provided through the through holes 2330, and, accordingly, as shown in FIG. 19, the upper width d5 of the recesses 2230 may be greater than the lower width d6 of the recesses 2230. In addition, the recesses 2230 may be extended to the grooves 2212 of the intermediate openings 2210 during the wet etching process. In the illustrated embodiment, the method of performing the wet etching process is substantially the same as described above with reference to FIG. 26, and thus a detailed description thereof will be omitted.

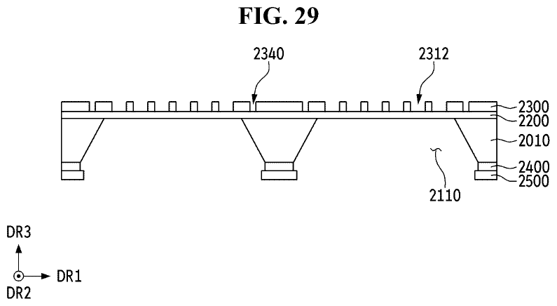

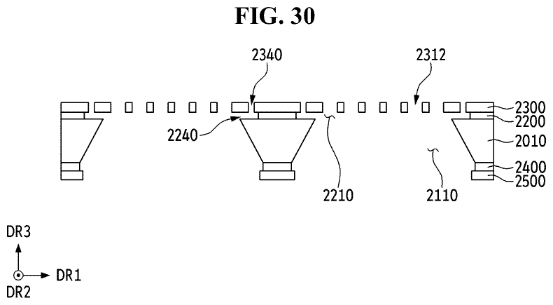

FIGS. 29 and 30 are schematic cross-sectional views illustrating another embodiment of a method of manufacturing a deposition mask according to the disclosure.

Referring to FIG. 29, the membrane 2300 may be patterned to define the pixel openings 2312 and the through slots 2340 exposing the intermediate inorganic film 2200. As shown in FIG. 20, the through slots 2340 may be arranged in a band shape surrounding the plurality of pixel openings 2312, that is, in a band shape surrounding the mask cell region 2310, and may extend along the circumference of the mask cell region 2310. In particular, the through slots 2340 may be defined simultaneously with the pixel openings 2312. In an embodiment, after forming on the membrane 2300 a photoresist pattern (not shown) that exposes portions where the pixel openings 2312 and the through slots 2340 are to be defined, an anisotropic etching process using this photoresist pattern as an etching mask may be performed to define the pixel openings 2312 and the through slots 2340 exposing the intermediate inorganic film 2200, for example.

After defining the pixel openings 2312 and the through slots 2340, the mask substrate 2010 may be patterned to define the plurality of cell openings 2110 exposing the intermediate inorganic film 2200. In the illustrated embodiment, the methods for forming the intermediate inorganic film 2200, the membrane 2300, the first rear inorganic film 2400, the second rear inorganic film 2500 and defining the cell openings 2110 are substantially the same as those described above with reference to FIGS. 22 to 25, and thus a detailed description thereof will be omitted here.

Referring to FIG. 30, the intermediate inorganic film 2200 may be patterned to define the intermediate openings 2210 extending to the pixel openings 2312 and the cell openings 2110 and the plurality of recesses 2240 arranged along the circumference of each of the intermediate openings 2210 and extended to the intermediate openings 2210. In this case, the recesses 2240 may extend in the same direction as that of the through slots 2340. In particular, the recesses 2240 may extend along the circumference of each of the intermediate openings 2210. In an embodiment, the intermediate openings 2210 and the recesses 2240 may be defined simultaneously through a wet etching process, and the through slots 2340 may serve as passages for providing an etchant during the wet etching process, for example. That is, the plurality of recesses 2240 may be defined by the etchant provided through the through slots 2340, and, accordingly, as shown in FIG. 21, the upper width d7 of the recesses 2240 may be greater than the lower width d8 of the recesses 2240. In addition, the recesses 2240 may be extended to the grooves 2212 of the intermediate openings 2210 during the wet etching process. In the illustrated embodiment, the method of performing the wet etching process is substantially the same as described above with reference to FIG. 26, and thus a detailed description thereof will be omitted.

The disclosure should not be construed as being limited to the embodiments set forth herein. Rather, these embodiments are provided so that this disclosure will be thorough and complete and will fully convey the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A deposition mask comprising:
a mask frame defining a cell opening;
an intermediate inorganic film disposed on the mask frame and defining an intermediate opening defined on the cell opening; and
a membrane disposed on the intermediate inorganic film and defining a plurality of pixel openings defined on the intermediate opening,
wherein the intermediate opening has a width greater than a width of the cell opening so that a groove having a band shape is defined between the mask frame and the membrane.

2. The deposition mask of claim 1, wherein a lower width of the intermediate opening is greater than an upper width of the cell opening, and an upper width of the intermediate opening is smaller than the lower width of the intermediate opening.

3. The deposition mask of claim 2, wherein a lower width of the cell opening is greater than the upper width of the cell opening.

4. The deposition mask of claim 1, wherein the intermediate inorganic film defines a plurality of recesses arranged along a circumference of the intermediate opening and extended to the intermediate opening.

5. The deposition mask of claim 4, wherein the membrane defines a plurality of through holes defined on the recesses.

6. The deposition mask of claim 4, wherein an upper width of the recesses is greater than a lower width of the recesses.

7. The deposition mask of claim 1, wherein the intermediate inorganic film defines a plurality of recesses arranged along a circumference of the intermediate opening, extending along the circumference of the intermediate opening, and extended to the intermediate opening.

8. The deposition mask of claim 7, wherein the membrane defines a plurality of through slots defined on the recesses and extending in a same direction as an extension direction of the recesses.

9. The deposition mask of claim 7, wherein an upper width of the recesses is greater than a lower width of the recesses.

10. The deposition mask of claim 1, wherein the mask frame comprises silicon, the membrane comprises silicon nitride, and the intermediate inorganic film comprises silicon oxide.

11. A method of manufacturing a deposition mask, the method comprising:
forming an intermediate inorganic film on a substrate;
forming a membrane on the intermediate inorganic film;
patterning the membrane to define a plurality of pixel openings exposing the intermediate inorganic film;
patterning the substrate to define a cell opening exposing the intermediate inorganic film; and
patterning the intermediate inorganic film to define an intermediate opening extending to the plurality of pixel openings and the cell opening,
wherein the intermediate opening has a width greater than a width of the cell opening so that a groove having a band shape is defined between the substrate and the membrane.

12. The method of claim 11, wherein the intermediate opening is defined by a wet etching process,
a lower width of the intermediate opening is greater than an upper width of the cell opening, and
an upper width of the intermediate opening is smaller than the lower width of the intermediate opening.

13. The method of claim 12, wherein the cell opening is defined by a wet etching process, and
a lower width of the cell opening is greater than the upper width of the cell opening.

14. The method of claim 11, further comprising patterning the intermediate inorganic film to define a plurality of recesses arranged along a circumference of the intermediate opening and extended to the intermediate opening.

15. The method of claim 14, further comprising patterning the membrane to define a plurality of through holes exposing the intermediate inorganic film,
wherein the through holes are arranged in a band shape surrounding the plurality of pixel openings and are defined simultaneously with the plurality of pixel openings, and
the recesses are extended to the through holes and are defined simultaneously with the intermediate opening by a wet etching process.

16. The method of claim 14, wherein an upper width of the recesses is greater than a lower width of the recesses.

17. The method of claim 11, further comprising patterning the intermediate inorganic film to define a plurality of recesses arranged along a circumference of the intermediate opening, extending along the circumference of the intermediate opening, and extended to the intermediate opening.

18. The method of claim 17, further comprising patterning the membrane to define a plurality of through slots exposing the intermediate inorganic film,
wherein the through slots are arranged in a band shape surrounding the plurality of pixel openings, extend in a same direction as an extension direction of the recesses, and are defined simultaneously with the plurality of pixel openings, and
the recesses are extended to the through slots and are defined simultaneously with the intermediate opening by a wet etching process.

19. The method of claim 17, wherein an upper width of the recesses is greater than a lower width of the recesses.

20. An electronic device comprising:
a display panel comprising:
a backplane substrate; and
light-emitting layers disposed on the backplane substrate by a deposition mask, the deposition mask comprising:
a mask frame defining a cell opening;
an intermediate inorganic film disposed on the mask frame and defining an intermediate opening defined on the cell opening; and
a membrane disposed on the intermediate inorganic film and defining a plurality of pixel openings defined on the intermediate opening,
wherein the intermediate opening has a width greater than a width of the cell opening so that a groove having a band shape is defined between the mask frame and the membrane.
